(19) United States
(12) Patent Application Publication
(10) Pub. No.: US 2026/0130206 A1
(43) Pub. Date: May 7, 2026

(54) METAL INTERCONNECT STRUCTURES AND METHODS THEREOF

(71) Applicant: Taiwan Semiconductor Manufacturing Company, Ltd., Hsinchu (TW)

(72) Inventors: Eric Paul Young, Hsinchu City (TW); Li-Hsin Chu, Hsinchu City (TW); Wen-Chih Chiang, Hsinchu City (TW); Yung-Lung Hsu, Hsinchu City (TW)

(73) Assignee: Taiwan Semiconductor Manufacturing Company, Ltd., Hsinchu (TW)

(21) Appl. No.: 18/940,222

(22) Filed: Nov. 7, 2024

(51) Int. Cl. H01L 23/532; H01L 21/768

(52) U.S. Cl. CPC H10W 20/4435; H10W 20/033; H10W 20/056; H10W 20/425; H10W 20/4407; H10W 20/4424; H10W 20/4441; H10W 20/4462

(57) ABSTRACT

A semiconductor device includes a plurality of metallization layers vertically disposed with respect to and electrically couple to a plurality of transistors. Each of the plurality of metallization layers includes a metal line and a metal via. Each of the metal lines and the metal vias are coupled to a barrier layer. The metal lines and the metal vias each essentially consist of a first material comprising copper (Cu), silver (Ag), and carbon (C). The barrier layer essentially consists of a second material including zirconium nitride (ZrN).

### BACKGROUND

The semiconductor industry has experienced rapid growth due to continuous improvements in integration density of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. With further technology developments in many areas like Artificial Intelligence (AI), more metal layers are required in semiconductor devices to support high computational requirements. However, increased number of metal layers in semiconductor devices may cause increased overall signal Resistance-Capacitance (RC) time delay, and thus may disadvantageously impact product performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example cross-sectional view of a semiconductor device including a large number of metal interconnect structures in accordance with some embodiments.

FIG. 2 is an example flow chart of a method for fabricating a semiconductor device including a large number of metal interconnect structures in accordance with some embodiments.

FIGS. 3, 4, 5, 6, 7 and 8 illustrate cross-sectional views of an example semiconductor device, during various fabrication stages, made by the method of FIG. 2 in accordance with some embodiments.

FIG. 9 are example chart diagrams illustrating impact of Resistance-Capacitance (RC) time delay on product performance of a semiconductor device.

FIG. 10 is an example diagram illustrating different overall via resistance performances of different example materials.

FIG. 11 is an example diagram illustrating different anti-permeation performances of different example materials.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor industry has experienced rapid growth due to continuous improvements in integration density of electronic components (e.g., transistors, diodes, resistors, capacitors, etc.). For example, back-end technologies begin with contact (e.g., W) connected to silicided front-end gate, source, and/or drain electrodes. These connections may be linked to e.g., silicided silicon first and then link to metal-gates or may be linked directly to metal-gates. Further inter-metal connections of a metal (e.g., Cu) with different thicknesses may be stacked until a pad of a material such as aluminum copper (AlCu) for far back-end bumping processes. With further technology developments in many areas like Artificial Intelligence (AI), more metal layers (or metallization layers) are required in semiconductor devices to support high computational requirements. However, increased number of metal layers in semiconductor devices may cause increased overall signal Resistance-Capacitance (RC) time delay, and thus may disadvantageously impact product performance of semiconductor devices.

The present disclosure provides various embodiments of a semiconductor device. In some embodiments, the semiconductor device includes, in a back end of line (BEOL) network, a plurality of metallization layers that are vertically disposed with respect to and electrically couple to a plurality of transistors, which are disposed in a front end of line (FEOL) network. In some embodiments, each of the plurality of metallization layers in the BEOL network includes a metal line and a metal via, combinedly forming an interconnect structure. In some embodiments, each of the metal line and the metal via is coupled to a barrier layer or surrounded at a bottom surface or sidewalls thereof by the barrier layer. In some embodiments, the metal line and the metal via each essentially consist of a first material that contains copper (Cu), silver (Ag), and carbon (C), and the barrier layer essentially consists of a second material that contains zirconium nitride (ZrN). In some embodiments, a ratio of an amount of silver (Ag) in the first material to a total amount of the first material in mass is greater than 30%. In some embodiments, a ratio of an amount of carbon (C) in the first material to a total amount of the first material in mass is in a range from 3% to 10%.

By replacing copper (Cu) with a metal compound or alloy (AgCuC) (Ag has an extremely low resistivity ρ=1.59×10−8) in the interconnect structures, smaller overall resistance of the interconnect structures can be achieved. With higher silver (Ag) concentration (e.g., over 30% by weight or mass) in the metal compound (the first material) of the interconnect structures, the interconnect structures can advantageously withstand back-end thermal processes with minimal change in resistivity compared to pure copper (Cu) alloy. In addition, by adding carbon (e.g., 3˜10% by weight or mass) in the first material of the interconnect structures, the electromigration effect of the first material can be improved when smaller dimension routing is required. Furthermore, by using zirconium nitride (ZrN) instead of tantalum nitride TaN as a second material of the barrier layer, further reduced resistivity can be achieved for the multi-layered interconnect structures. As such, a large number of metal interconnect structures in the BEOL network of the semiconductor device according to the present disclosure can be achieved with a reduced resistance, and thus advantageously leads to a reduced overall signal Resistance-Capacitance (RC) time delay, thereby improving product performance of the semiconductor device.

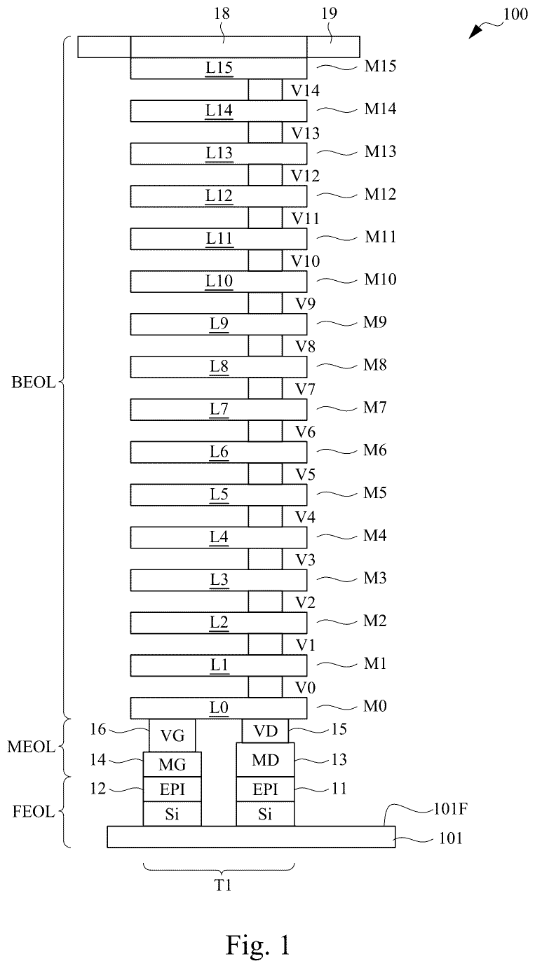

FIG. 1 is an example cross-sectional view of a semiconductor device 100 including a large number of metal interconnect structures in accordance with some embodiments. In some embodiments, the semiconductor device 100 includes a plurality of transistors (e.g., a transistor T1 as shown in FIG. 1) formed along a front surface 101F of a substrate 101 in a front end of line (FEOL) network, and a plurality of metallization layers (e.g., M0, M1, M2, M3 . . . M15 etc.) formed in a back end of line (BEOL) network. In some embodiments, the transistor T1 includes at least a source/drain terminal 11, and a gate terminal 12. In some embodiments, the plurality of metallization layers are vertically disposed with respect to and electrically coupled to the plurality of transistors (e.g., the transistor T1). FIG. 1 simply shows an example semiconductor device 100 having sixteen metallization layers (such as M0, M1, M2, M3, . . . M15) on the front side of the semiconductor device for illustration purposes, it thus should be understood that the semiconductor device 100 can include any number of metallization layers on the front side thereof, and can also include other features/structures, while remaining within the scope of the present disclosure. In addition, the semiconductor device 100 can also include a plurality of back-side metallization layers (not shown) having identical or similar structures (such as the interconnect structures that will be described later) to the front-side metallization layers (such as M0, M1, M2, M3 . . . M15 in FIG. 1).

In some embodiments, the plurality of metallization layers (e.g., M0, M1, M2, M3, . . . M15 etc.) each include a number of metal interconnect structures (such as metal lines and metal vias), and are typically disposed over the front surface 101F of the substrate 101. For example, a bottom-most metallization layer M0 includes metal interconnect structures, such as at least a metal line L0 and at least a metal via V0; metallization layer M1 includes metal interconnect structures, such as at least a metal line L1 and at least a metal via V1; metallization layer M2 includes metal interconnect structures, such as at least a metal line L2 and at least a metal via V2; metallization layer M3 includes metal interconnect structures, such as at least a metal line L3 and at least a metal via V3; metallization layer M4 includes metal interconnect structures, such as at least a metal line L4 and at least a metal via V4; metallization layer M5 includes metal interconnect structures, such as at least a metal line L5 and at least a metal via V5; . . . metallization layer M14 includes metal interconnect structures, such as at least a metal line L14 and at least a metal via V14; and top-most metallization layer M15 includes metal interconnect structures, such as at least a metal line L5 and at least a metal via V15.

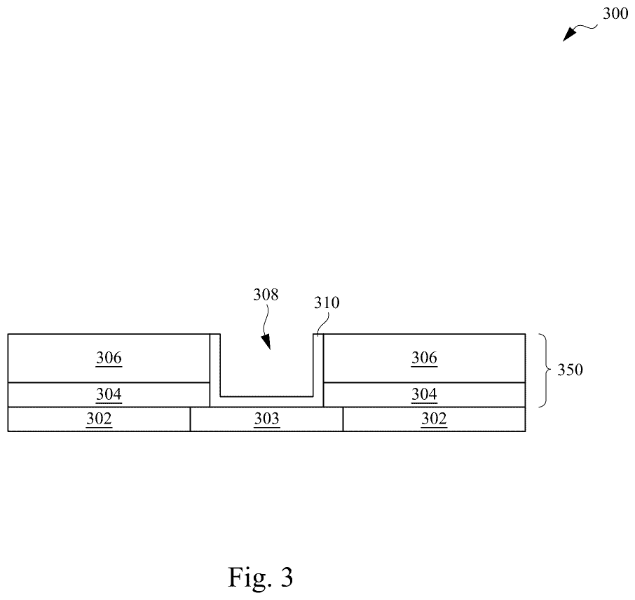

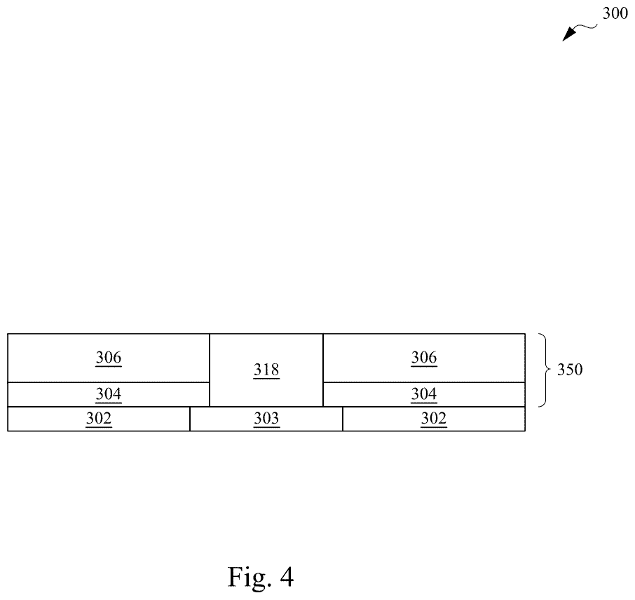

In some embodiments, the plurality of metallization layers (e.g., M0, M1, M2, M3, . . . M15) each (such as M3) is embedded in an inter-layer dielectric (ILD) layer or inter-metal dielectric (IMD) layer. The IMD/ILD may include one or more of a low-k dielectric layer (i.e., a dielectric with a dielectric constant less than about 3.9), an ultra-low-k dielectric layer, or an oxide (e.g., silicon oxide). In some embodiments, a metallization layer (e.g., M3) of the plurality of metallization layers includes metal interconnect structures such as a metal line (e.g., L3) and a metal via (e.g., V3). In some embodiments, the metal interconnect structures are coupled to barrier structures (such as line barriers or via barriers). In some embodiments, a metal line (e.g., L3) is coupled to a line barrier layer, and a metal via (e.g., V3) is coupled to a via barrier layer. More details about the IMD layer and the barrier structures are recited later with respect to FIG. 3. In other embodiments, the barrier structures such as line barrier layers and via barrier layers are optional, referring to e.g., FIGS. 4, 5, 6, 7 and 8.

In some embodiments, the semiconductor device 100 further includes a number of middle-end conductor structures (such as MD 13, MG 14, VD 15, and VG 16) that are formed in a middle end of line (MEOL) network, and each of the middle-end conductor structures can provide an electrical connection path for a corresponding gate structure or source/drain structure. In some embodiments, the middle-end conductor structure 13 is formed as a metal line structure (sometimes referred to as “MD”, meaning “metal to drain”) and in electrical contact with a source/drain 11 of the transistor T1, and the middle-end conductor structure 15 is formed as a metal via structure (sometimes referred to as “VD”, meaning “via to drain”) in electrical contact with the MD 13. In some embodiments, the VD 15 is also in electrical contact with the bottom-most metallization layer M0 through a bottom-most metal line (e.g., L0) thereof. In some embodiments, the middle-end conductor structure 14 is formed as a metal line structure (sometimes referred to as “MG”, meaning “metal to gate”) and in electrical contact with the gate structure 12 of the transistor T1, and the middle-end conductor structure 16 is formed as a metal via structure (sometimes referred to as “VG”, meaning “via to gate”) in electrical contact with the MG 14. In some embodiments, the VG 16 is also in electrical contact with the bottom-most metallization layer M0 through the bottom-most metal line (e.g., L0) thereof. In some embodiments, the conductor structures (such as MD 13, MG 14, VD 15, and VG 16) in the MEOL network are made of a metal material that includes tungsten (W). In other embodiments, the conductor structures (such as MD 13, MG 14, VD 15, and VG 16) in the MEOL network are made of the first metal material that is used to form the metal interconnect structures (e.g., M3) in the plurality of metallization layers (e.g., M0, M1, M2, M3, . . . M15) in the BEOL network. As such, the bottom-most metallization layer (e.g., M0) of the plurality of metallization layers (e.g., M0, M1, M2, M3 . . . M15) formed in the BEOL network is electrically coupled to the source/drain terminal 11 of the transistor T1 through metal structures VD 15 and MD 13 formed in the MEOL network, and is electrically coupled to the gate terminal 12 of the transistor T1 through metal structures VG 16 and MG 14 formed in the MEOL network.

In some embodiments, the metal line (e.g., L3) and the metal via (e.g., V3) of interconnect structures in a metallization layer (e.g., M3) each essentially consist of a first metal compound or metal alloy (e.g., AgCuC) that includes silver (Ag), copper (Cu), and carbon (C). In some embodiments, a ratio of an amount of silver in the first metal alloy to a total amount of the first metal alloy by weight or mass is greater than 30%, and in other embodiments, the ratio of the amount of silver in the first metal alloy to the total amount of the first metal alloy by weight or mass is greater than 35%. In some embodiments, a ratio of an amount of carbon in the first metal alloy to a total amount of the first metal alloy by weight or mass is in a range from 3% to 10%, and in other embodiments, the ratio of the amount of carbon in the first metal alloy to the total amount of the first metal alloy by weight or mass is in a range from 5% to 8%.

In some embodiments, a plurality of metal pads (e.g., a metal pad 18) may be formed within a redistribution layer (RDL) 19, which is formed over the top-most metallization layer (e.g., M15) of the plurality of metallization layers (e.g., Mo, M1, M2, M3, . . . and M15) at a far back end of the BEOL network for far back-end bumping processes or purposes and can be used to connect with one or more other semiconductor devices (not shown). In some embodiments, the metal pads 18 are made of a metal alloy material that is different from the first metal alloy material of the metal interconnect structures in the plurality of metallization layer (e.g., M0, M1, M2, M3, . . . and M15). In some embodiments, the metal pads 18 are made of a metal alloy material (e.g., AlSiCu) that includes aluminum (Al), silicon (Si), and copper (Cu).

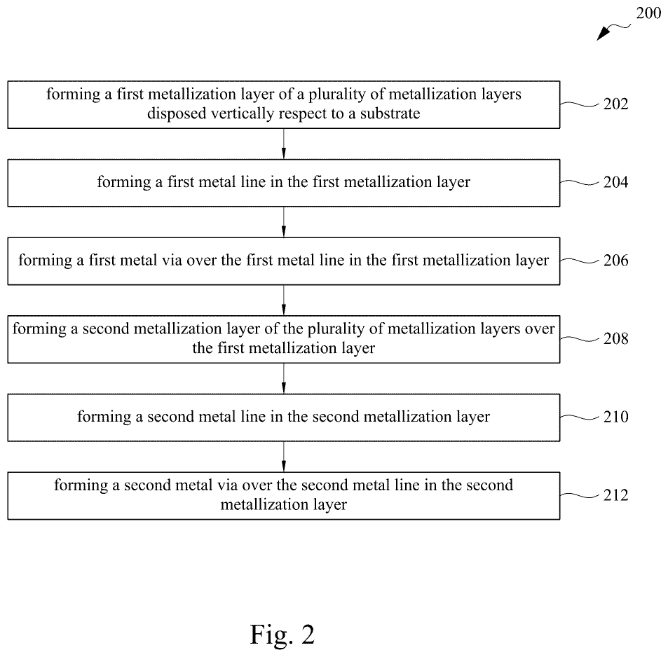

FIG. 2 is an example flow chart of a method 200 for fabricating a semiconductor device 300 (corresponding to semiconductor device 100 in FIG. 1) that includes a large number of metal interconnect structures in accordance with some embodiments. As shown in FIG. 2, the method 200 includes forming a first metallization layer of a plurality of metallization layers disposed vertically respect to a substrate at step 202; forming a first metal line in the first metallization layer at step 204; forming a first metal via over the first metal line in the first metallization layer at step 206; forming a second metallization layer of the plurality of metallization layers over the first metallization layer at step 208; forming a second metal line in the second metallization layer at step 210; and forming a second metal via over the second metal line in the second metallization layer at step 212.

FIGS. 3, 4, 5, 6, 7 and 8 illustrate cross-sectional views of an example semiconductor device 300, during various fabrication stages or steps, made by the method 200 of FIG. 2 in accordance with some embodiments. The semiconductor device 300 may be included in a microprocessor, memory cell, and/or other integrated circuit (IC). It is noted that the method 200 of FIG. 2 does not produce a completed semiconductor device 300. A completed semiconductor device 300 may be fabricated using complementary metal-oxide-semiconductor (CMOS) technology processing. Accordingly, it is understood that additional processes may be provided before, during, and after the method 200 of FIG. 2, and that some other processes may only be briefly described herein. Also, FIGS. 2-8 are simplified for a better understanding of the present disclosure. For example, although the figures illustrate the semiconductor device 200, it is understood the IC may comprise a number of other devices comprising transistors, resistors, capacitors, inductors, fuses, etc. Although FIGS. 2-8 simply show a semiconductor device 300 having two metallization layers (such as M0 and M1) are formed for illustration purposes, it thus should be understood that the semiconductor device 300 can include any number of metallization layers, while remaining within the scope of the present disclosure.

Referring to FIGS. 2 and 3, the method 200 begins at step 202 in which a first metallization layer 350 (e.g., a bottom-most M0) of a plurality of metallization layers (e.g., M0, M1, M2, M3, . . . M15 in FIG. 1) is formed vertically respect to a substrate 302. Referring to FIG. 3, the first metallization layer 350 includes an etch stop layer (or etch stop material) 304 and a dielectric layer (or dielectric material) 306, and a recess (or cavity) 308 formed in the etch stop layer 304 and the dielectric layer 306. In some embodiments, the etch stop layer 304 and the dielectric layer 306 can form a portion of an inter-metal dielectric (IMD) layer 350. Such an IMD layer 350 is sometimes referred to as a metallization layer that includes one or more interconnect structures embedded within a corresponding dielectric layer and a corresponding etch stop layer. The interconnect structures can be formed of a material, such as a first metal alloy AgCuC that contains silver (Ag), copper (Cu), and carbon (C). In some embodiments, the etch stop layer 304 is formed over a semiconductor substrate 302 and under the dielectric layer 306. In some embodiments, as shown in FIG. 3, the recess 308 is formed in the dielectric layer 306 and the etch stop layer 304, and the recess 308 extends through the dielectric layer 306 and the etch stop layer 304.

The semiconductor substrate 302 is a substrate as employed in a semiconductor integrated circuit fabrication, and integrated circuits can be formed therein and/or thereupon. The term “semiconductor substrate” as used herein refers to as any construction comprising semiconductor material, for example, a silicon substrate with or without an epitaxial layer, a silicon-on-insulator substrate containing a buried insulator layer, or a substrate with a silicon germanium layer. The term “integrated circuits” as used herein refers to electronic circuits having multiple individual circuit elements, such as transistors, diodes, resistors, capacitors, inductors, and other active and passive semiconductor devices.

A conductive region 303 may be formed in and/or on the semiconductor substrate 302 (e.g., in the semiconductor substrate 302 exposed by the recess 308). The conductive region 303 may be a portion of conductive routes and has exposed surfaces that may be treated by a planarization process, such as chemical mechanical polishing. Suitable materials for the conductive region 303 may include, but not limited to, for example copper, aluminum, copper alloy, or other mobile conductive materials. The semiconductor substrate 302 containing such a copper conductive region 303 may be the first or any subsequent metallization layers (or metallization levels) metallization layer of the semiconductor device 300.

The etch stop layer 304 functions for controlling the end point during subsequent etching processes. In some embodiments, the etch stop layer 304 is formed of silicon oxide, silicon nitride, silicon carbide, silicon oxynitride or combinations thereof. In some embodiments, the etch stop layer 304 has a thickness of about 10 angstroms to about 1000 angstroms. The etch stop layer 304 is formed through any of a variety of deposition techniques, including, LPCVD (low-pressure chemical vapor deposition), APCVD (atmospheric-pressure chemical vapor deposition), PECVD (plasma-enhanced chemical vapor deposition), PVD (physical vapor deposition), sputtering, and future-developed deposition procedures.

The dielectric layer 306 may be a single layer or a multi-layered structure. In some embodiments, the dielectric layer 306 with a thickness varies with the applied technology, for example a thickness of about 1000 angstroms to about 30000 angstroms. In some embodiments, the dielectric layer 306 is silicon oxide, carbon-doped silicon oxide, a comparatively low dielectric constant (k value) dielectric material with a k value less than about 4.0, or combinations thereof. In some embodiments, the dielectric layer 306 is formed of a material, including low-k dielectric material, extreme low-k dielectric material, porous low-k dielectric material, and combinations thereof. The term “low-k” is intended to define a dielectric constant of a dielectric material of 3.0 or less. The term “extreme low-k (ELK)” means a dielectric constant of 2.5 or less, and preferably between 1.9 and 2.5. The term “porous low-k” refers to a dielectric constant of a dielectric material of 2.0 or less, and preferably 1.5 or less. A wide variety of low-k materials may be employed in accordance with embodiments, for example, spin-on inorganic dielectrics, spin-on organic dielectrics, porous dielectric materials, organic polymer, organic silica glass, FSG (SiOF series material), HSQ (hydrogen silsesquioxane) series material, MSQ (methyl silsesquioxane) series material, or porous organic series material. In some embodiments, the dielectric layer 306 is deposited through any of a variety of techniques, such as chemical vapor deposition (CVD), physical vapor deposition (PVD), atomic layer deposition (ALD), remote plasma enhanced chemical vapor deposition (RPECVD), liquid source misted chemical deposition (LSMCD), coating, spin-coating or another process that is adapted to form a thin film layer over the substrate.

In some embodiments, the dielectric layer 306 is a nitrogen-containing layer, a carbon-containing layer, or a carbon-containing and nitrogen-containing layer for increasing corrosion resistance during a subsequent chemical mechanical polishing (CMP) process and/or increasing electromigration resistance. In one embodiment, the dielectric layer 306 is a silicon-containing and nitrogen-containing dielectric layer. In another embodiment, the dielectric layer 306 is a silicon-containing and carbon-containing dielectric layer. In yet another embodiment, the dielectric layer 306 is a silicon-containing, nitrogen-containing, and carbon-containing dielectric layer. In one embodiment, the dielectric layer 306 has a ratio by weight of carbon to silicon about equal or greater than 0.5. In another embodiment, the dielectric layer 306 has a ratio by weight of nitrogen to silicon about equal or greater than 0.3. In yet another embodiment, the dielectric layer 306 has a ratio by weight of carbon to silicon about equal or greater than 0.5 and a ratio by weight of nitrogen to silicon about equal or greater than 0.3.

The recess 308 is patterned in the dielectric layer 306 and the etch stop layer 304 to define a contact region on the semiconductor substrate 302. In some embodiments, the recess 308 can be used for forming an opening first and then forming a metal via, and in other embodiments, the recess 308 can be used for forming a trench first and then forming a metal line. Various techniques, such as lithography, etching, and CMP processes, etc. can be used to form the recess 308 in the dielectric layer 306 and the etch stop layer 304 of the IMD layer 350.

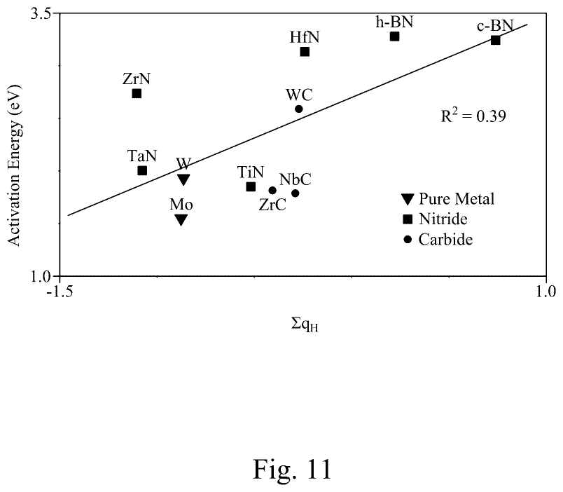

In some embodiments, as shown in FIG. 3, a barrier layer 310 is formed to line a bottom surface and sidewalls of the recess 308 and over the dielectric layer 306. In other embodiments, as shown later in FIGS. 4, 5, 6, 7 and 8, the barrier layer 310 in FIG. 3 is optional. The barrier layer 310 may function as a barrier to prevent a subsequently formed interconnect conductor (e.g., a metal line or a metal via) from diffusing into e.g., the abutting or underlying dielectric layer 306. In some embodiments, the barrier layer 310 is made of a second metal compound or alloy material such as zirconium nitride (ZrN), which advantageously has good conductivity (lower resistivity), excellent barrier properties (e.g., excellent anti-permeation as shown in FIG. 11), mechanical strength, and chemical stability. Various processes, such as sputtering, evaporation, Chemical Vapor Deposition (CVD), plasma-enhanced chemical vapor deposition (PECVD), atomic layer deposition (ALD) and electrochemical deposition (ECD), can be used to form the barrier layer 310. In some embodiments, the barrier layer 310 has a thickness of about 10 angstrom to about 250 angstroms.

Referring to FIGS. 2 and 4, the method 200 proceeds to step 204 in which a first metal line 318 is formed in the first metallization layer 350. In some embodiments, the recess 308 in FIG. 3 is filled with a first metal compound or alloy material 318 to form the first metal line 318. In some embodiments, the first metal alloy material 318 is formed as an interconnect structure in the dielectric layer 306 and the etch stop layer 304 of the first metallization layer 350. In some embodiments, the first metal alloy material 318 is deposited by an electro-chemical plating (ECP) process, physical vapor deposition (PVD), chemical vapor deposition (CVD), plasma enhanced CVD (PECVD), low pressure CVD (LPCVD), atomic layer deposition (ALD), or other well-known deposition techniques. In some embodiments, the first metal alloy material 318 includes silver (Ag), copper (Cu), and carbon (C). In some embodiments, a ratio of an amount of silver in the first metal alloy material 318 to a total amount of the first metal alloy material 318 by weight or mass is greater than 30%, and in other embodiments, the ratio of the amount of silver in the first metal alloy material 318 to the total amount of the first metal alloy material 318 by weight or mass is greater than 35%. In some embodiments, a ratio of an amount of carbon in the first metal alloy material 318 to a total amount of the first metal alloy material 318 by weight or mass is in a range from 3% to 10%, and in other embodiments, the ratio of the amount of carbon in the first metal alloy material 318 to the total amount of the first metal alloy material 318 by weight or mass is in a range from 5% to 8%.

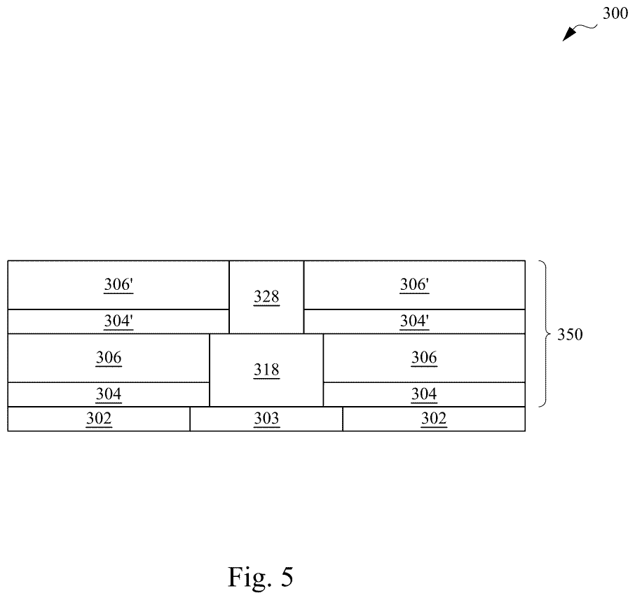

Referring to FIGS. 2 and 5, the method 200 proceeds to step 206 in which a first metal via 328 is formed over the first metal line 318 in the first metallization layer 350. Referring to FIG. 5, the first metallization layer 350 further includes an additional etch stop layer (or etch stop material) 304′ over the dielectric layer 306 of the first metallization layer 350 and an additional dielectric layer 306′ over the additional etch stop layer 304′, and the first metal via 328 formed in the additional etch stop layer 304′ and the additional dielectric layer 306′ of the first metallization layer 350. The methods or processes of forming the first metal via 328 is similar to those of forming the first metal line 318, except that the patterning of the first metal via 328 is different from the patterning of the first metal line 318. In some embodiments, the first metal via 328 and the first metal line 318 are made of an identical metal compound or alloy, i.e., the first metal alloy (AgCuC) that includes silver (Ag), copper (Cu), and carbon (C). In some embodiments, a ratio of an amount of silver in the first metal via 328 to a total amount of the first metal via 328 by weight or mass is greater than 30%, and in other embodiments, the ratio of the amount of silver in the first metal via 328 to the total amount of the first metal via 328 by weight or mass is greater than 35%. In some embodiments, a ratio of an amount of carbon in the first metal via 328 to a total amount of the first metal via 328 by weight or mass is in a range from 3% to 10%, and in other embodiments, the ratio of the amount of carbon in the first metal via 328 to the total amount of the first metal via 328 by weight or mass is in a range from 5% to 8%.

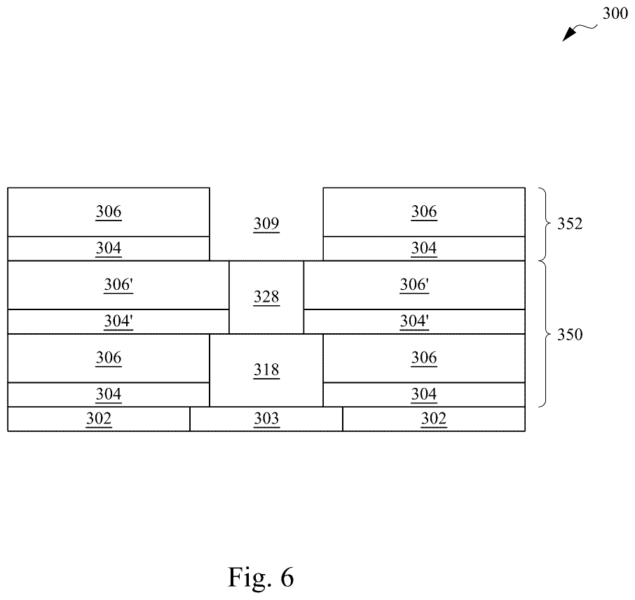

Referring to FIGS. 2 and 6, the method 200 proceeds to step 208 in which a second metallization layer 352 (e.g., M1) of the plurality of metallization layers (e.g., M0, M1, M2, M3, . . . M15 in FIG. 1) is formed over the first metallization layer 350 (e.g., M0). Referring to FIG. 6, similar to the first metallization layer 350, the second metallization layer 352 includes an etch stop layer (or etch stop material) 304 and a dielectric layer (or dielectric material) 306, and a recess (or cavity) 309 formed in the etch stop layer 304 and the dielectric layer 306 of the second metallization layer 352. In some embodiments, the etch stop layer 304 and the dielectric layer 306 in the second metallization layer 352 are made of the same materials of the etch stop layer 304 and the dielectric layer 306 in the first metallization layer 350. In some embodiments, as shown in FIG. 6, the recess 309 is formed in the dielectric layer 306 and the etch stop layer 304 of the second metallization layer 352, extends through the dielectric layer 306 and the etch stop layer 304 of the second metallization layer 352, and can be used to form a conductive interconnect structure later in the second metallization layer 352. Various techniques, such as lithographic, etching, and CMP processes, etc. can be used to form the recess 309 in the dielectric layer 306 and the etch stop layer 304 of the second metallization layer 352.

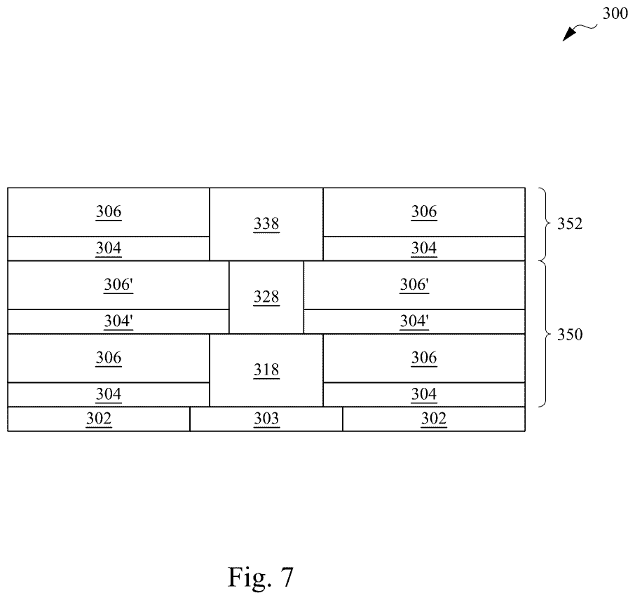

Referring to FIGS. 2 and 7, the method 200 proceeds to step 210 in which a second metal line 338 is formed in the second metallization layer 352. In some embodiments, the recess 309 in FIG. 6 is filled with the first metal compound or alloy to form the second metal line 338. In some embodiments, the second metal line 338 is formed as an interconnect structure in the dielectric layer 306 and the etch stop layer 304 of the second metallization layer 352. In some embodiments, the first metal alloy material (AgCuC) used to form the first metal line 318 is also used to form the second metal line 338, and includes silver (Ag), copper (Cu), and carbon (C). In some embodiments, a ratio of an amount of silver in the second metal line 338 to a total amount of the second metal line 338 by weight or mass is greater than 30%, and in other embodiments, the ratio of the amount of silver in the second metal line 338 to the total amount of the second metal line 338 by weight or mass is greater than 35%. In some embodiments, a ratio of an amount of carbon in the second metal line 338 to a total amount of the second metal line 338 by weight or mass is in a range from 3% to 10%, and in other embodiments, the ratio of the amount of carbon in the second metal line 338 to the total amount of the second metal line 338 by weight or mass is in a range from 5% to 8%. In some embodiments, the second metal line 338 is deposited by an electro-chemical plating (ECP) process, physical vapor deposition (PVD), chemical vapor deposition (CVD), plasma enhanced CVD (PECVD), low pressure CVD (LPCVD), atomic layer deposition (ALD), or other well-known deposition techniques.

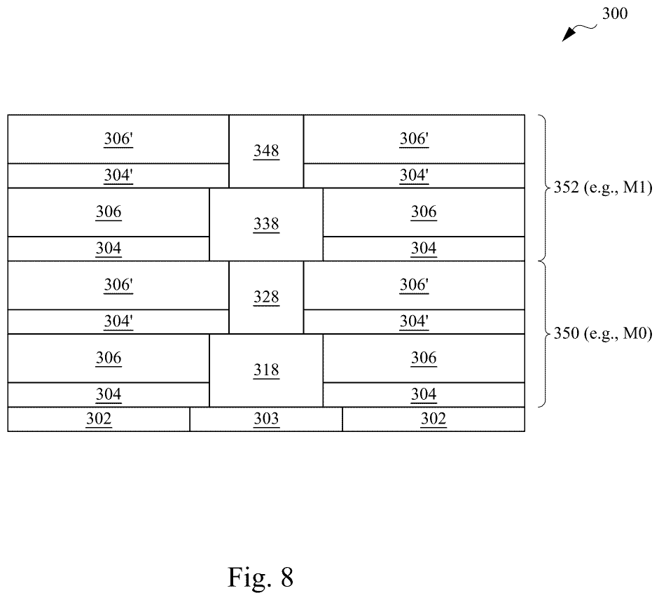

Referring to FIGS. 2 and 8, the method 200 proceeds to step 212 in which a second metal via 348 over and in contact with the second metal line 338 is formed in the second metallization layer 352. Referring to FIG. 8, the second metallization layer 352 further includes an additional etch stop layer (or etch stop material) 304′ over the dielectric layer 306 therein, an additional dielectric layer 306′ over the additional etch stop layer 304′ therein, and the second metal via 348 formed in the additional etch stop layer 304′ and the additional dielectric layer 306′ of the second metallization layer 352. The methods or processes of forming the second metal via 348 in the second metallization layer 352 is identical or similar to those of forming the first metal via 328 the first metallization layer 350. In some embodiments, the second metal via 348 is made of the first metal alloy (AgCuC) that includes silver (Ag), copper (Cu), and carbon (C). In some embodiments, a ratio of an amount of silver in the second metal via 348 to a total amount of the second metal via 348 by weight or mass is greater than 30%, and in other embodiments, the ratio of the amount of silver in the second metal via 348 to the total amount of the second metal via 348 by weight or mass is greater than 35%. In some embodiments, a ratio of an amount of carbon in the second metal via 348 to a total amount of the second metal via 348 by weight or mass is in a range from 3% to 10%, and in other embodiments, the ratio of the amount of carbon in the second metal via 348 to the total amount of the second metal via 348 by weight or mass is in a range from 5% to 8%.

In some embodiments, the steps or stages as shown in FIGS. 3-8 can be repeated such that a large number of metallization layers (such as M0, M1, M2, M3 . . . M15 etc.) each (each M3) including interconnect structures (such as L3 and V3) can be formed in the BEOL network. At least due to the use of the first metal material (e.g., AgCuC) containing silver (Ag), copper (Cu) and carbon (C) to form interconnect structures and the use of a second metal material zirconium nitride (ZrN) to form barrier layers in metallization layers, a large number of metallization layers in the semiconductor device according to the present disclosure can have a reduced resistance, and thus overall signal RC time delay can be reduced, thereby advantageously improving product performance of the semiconductor device.

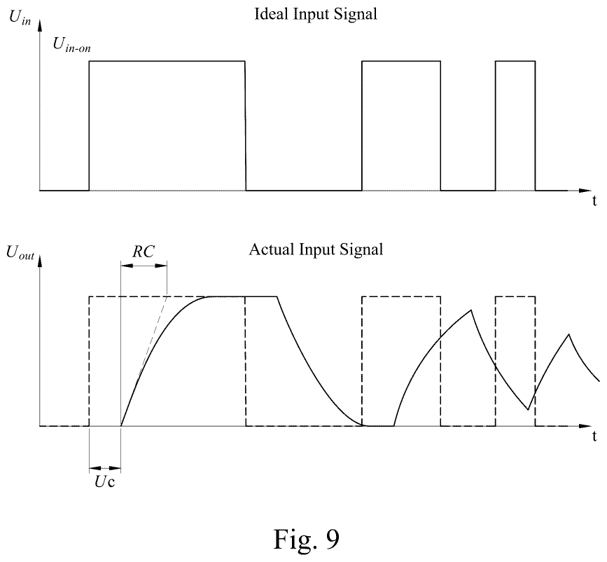

FIG. 9 are example chart diagrams illustrating impact of Resistance-Capacitance (RC) time delay on product performance of a semiconductor device. The upper chart in FIG. 9 illustrates an ideal input signal without an impact of RC time delay, while the lower chart in FIG. 9 illustrates an input signal impacted by a RC time delay. Advanced technologies (e.g., AI technologies) may require more metallization layers to meet their high computational requirements. However, as shown in FIG. 9, increasing number of metallization layers may cause greater overall signal RC time delay, which may disadvantageously impact signal performance of a semiconductor device.

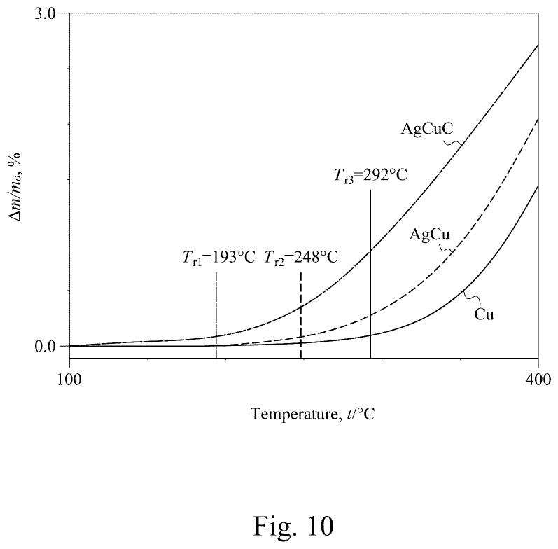

FIG. 10 is an example diagram illustrating different overall via resistance performances of different example materials, such as pure copper (Cu), a metal alloy AgCu containing silver (Ag) and copper (Cu), and another metal alloy AgCuC containing silver (Ag), copper (Cu) and carbon (C). As shown in FIG. 10, compared to a pure Cu alloy interconnect via, an AgCu interconnect via (Ag resistivity ρ=1.59×10⁻⁸) allows for smaller overall via resistance, thereby reducing RC time delay. In addition, compared to a AgCu alloy interconnect via, an AgCuC interconnect via allows for even smaller overall via resistance, thereby reducing RC time delay. It is noted that an AgCu interconnect via or an AgCuC interconnect via with a higher Ag concentration (˜30% by weight) can withstand back-end thermal processes with minimal change in resistivity compared to a pure Cu alloy interconnect via. In addition, it is also noted that having carbon (e.g., 3˜10% by weight) in the AgCuC interconnect via can result in an improved electromigration effect in the interconnect via, when smaller dimension routing is required.

FIG. 11 is an example diagram illustrating different anti-permeation performances of different example materials. As shown in FIG. 11, changing a material of a barrier layer coupled to an interconnect structure (e.g., a metal line or a metal via) in a metallization layer of a plurality of metallization layers from, e.g., tantalum nitride (TaN) (having resistivity ρ=240˜1140 μΩ-cm), to e.g., zirconium nitride (ZrN) (having resistivity ρ=12 μΩ-cm), can further reduce overall resistivity of the interconnect structure, thereby reducing resistivity of all the interconnect structures in the plurality of metallization layers (e.g., M0, M1, M2, M3, . . . M15 etc.). ZrN advantageously has lower resistivity than e.g., TaN. In addition, as shown in FIG. 11, compared to TaN material, ZrN material has much better anti-permeation property, and thus requires much higher energy (e.g., activation energy) to permeate therethrough, thereby resulting in improved signal performance of a semiconductor device.

As such due to the use of the first metal material (AgCuC) to form interconnect structures and the use of a second material (ZrN) to form barrier layers coupled to the interconnect structures in metallization layers, a large number of metallization layers in the semiconductor device according to the present disclosure can be formed having reduced overall resistance and increased anti-permeation capability, thereby advantageously improving product performance of the semiconductor device.

In one aspect of the present disclosure, a semiconductor device is disclosed. The semiconductor device includes a plurality of metallization layers vertically disposed with respect to and electrically couple to a plurality of transistors. Each of the plurality of metallization layers includes a metal line and a metal via electrically coupled to each other, and each of the metal line and the metal via is coupled to a barrier layer. The metal line and the metal via each essentially consist of a first material comprising copper (Cu), silver (Ag), and carbon (C). The barrier layer essentially consists of a second material that includes zirconium nitride (ZrN).

In another aspect of the present disclosure, a semiconductor device is disclosed. The semiconductor device includes a plurality of metallization layers vertically disposed with respect to and electrically coupled to a transistor formed on a substrate, each of the plurality of metallization layers including a metal line and a metal via electrically coupled to each other. The metal line and the metal via each essentially consist of a first material comprising copper (Cu), silver (Ag), and carbon (C).

In yet another aspect of the present disclosure, a method for forming memory devices is disclosed. The method includes forming a first metallization layer of a plurality of metallization layers disposed vertically respect to a substrate; forming a first metal line in the first metallization layer; forming a first metal via over the first metal line in the first metallization layer; forming a second metallization layer of the plurality of metallization layers over the first metallization layer; forming a second metal line in the second metallization layer; and forming a second metal via over the second metal line in the second metallization layer. The first metal line, the first metal via, the second metal line, and the second metal via each essentially consist of a first material comprising copper (Cu), silver (Ag), and carbon (C).

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of metallization layers vertically disposed with respect to and electrically coupled to a plurality of transistors, each of the plurality of metallization layers comprising a metal line and a metal via electrically coupled to each other, and each of the metal lines and the metal vias are coupled to a barrier layer,
wherein the metal lines and the metal vias each essentially consist of a first material comprising copper (Cu), silver (Ag), and carbon (C), and
wherein the barrier layer essentially consists of a second material comprising zirconium nitride (ZrN).

2. The semiconductor device of claim 1, wherein a ratio of an amount of silver in the first material to a total amount of the first material in mass is greater than 30%.

3. The semiconductor device of claim 1, wherein a ratio of an amount of silver in the first material to a total amount of the first material in mass is greater than 35%.

4. The semiconductor device of claim 1, wherein a ratio of an amount of carbon in the first material to a total amount of the first material in mass is in a range from 3% to 10%.

5. The semiconductor device of claim 1, wherein a ratio of an amount of carbon in the first material to a total amount of the first material in mass is in a range from 5% to 8%.

6. The semiconductor device of claim 1, wherein a bottom-most via in a bottom-most metallization layer of the plurality of metallization layers is electrically coupled to one of the plurality of transistors through a metal contact made of a third material.

7. The semiconductor device of claim 6, wherein the third material comprises tungsten (W).

8. The semiconductor device of claim 1, further comprising a redistribution layer (RDL) disposed over the plurality of metallization layers, and coupled to a top-most metallization layer of the plurality of metallization layers.

9. The semiconductor device of claim 8, wherein the redistribution layer is made of a fourth material (AlSiCu) comprising aluminum (Al), silicon (Si), and copper (Cu).

10. A semiconductor device, comprising:
a plurality of metallization layers vertically disposed with respect to and electrically coupled to a transistor formed on a substrate, each of the plurality of metallization layers comprising a metal line and a metal via electrically coupled to each other,
wherein the metal line and the metal via each essentially consist of a first material comprising copper (Cu), silver (Ag), and carbon (C).

11. The semiconductor device of claim 10, wherein each of the metal lines and the metal vias are at least partially surrounded at a bottom surface and sidewalls thereof by a barrier layer.

12. The semiconductor device of claim 11, wherein the barrier layer is made of a second material comprising zirconium nitride (ZrN).

13. The semiconductor device of claim 10, wherein a ratio of an amount of silver in the first material to a total amount of the first material in mass is greater than 30%.

14. The semiconductor device of claim 10, wherein a ratio of an amount of carbon in the first material to a total amount of the first material in mass is in a range from 3% to 10%.

15. A method of manufacturing a semiconductor device, comprising:
forming a first metallization layer of a plurality of metallization layers disposed vertically respect to a substrate;
forming a first metal line in the first metallization layer;
forming a first metal via over the first metal line in the first metallization layer;
forming a second metallization layer of the plurality of metallization layers over the first metallization layer;
forming a second metal line in the second metallization layer; and
forming a second metal via over the second metal line in the second metallization layer,
wherein the first metal line, the first metal via, the second metal line, and the second metal via each essentially consist of a first material comprising copper (Cu), silver (Ag), and carbon (C).

16. The method of claim 15, wherein the first metal line is electrically coupled to the first metal via, wherein the second metal line is electrically coupled to the first metal via, and wherein the second metal via is electrically coupled to the second metal line.

17. The method of claim 15, wherein a ratio of an amount of silver in the first material to a total amount in the first material in mass is greater than 30%.

18. The method of claim 15, wherein a ratio of an amount of carbon in the first material to a total amount of the first material in mass is in a range from 3% to 10%.

19. The method of claim 15, further comprising:
forming a first line barrier layer coupled to the first metal line at a bottom surface and sidewalls of the first metal line in the first metallization layer, posting forming the first metal line;
forming a first via barrier layer coupled to the first metal via at a bottom surface and sidewalls of the first metal via in the first metallization layer, posting forming the first metal via;
forming a second line barrier layer coupled to the second metal line at a bottom surface and sidewalls of the second metal line in the second metallization layer, posting forming the second metal line; and
forming a second via barrier layer coupled to the second metal via at a bottom surface and sidewalls of the second metal via in the second metallization layer, posting forming the second metal via.

20. The method of claim 19, wherein the first line barrier layer, the first via barrier layer, the second line barrier layer, and the second via barrier layer are made of a second material comprising zirconium nitride (ZrN).
